(19) United States
(12) Patent Application Publication
(10) Pub. No.: US 2004/0012021 A1
(43) Pub. Date: Jan. 22, 2004

(54) Semiconductor device and optical device including the same

(75) Inventors: Makoto Hosokawa, Nara (JP); Takahiro Takimoto, Tenri-shi (JP); Toshimitsu Kasamatsu, Tenri-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka (JP)

(21) Appl. No.: 10/616,095

(22) Filed: Jul. 8, 2003

(30) Foreign Application Priority Data
Jul. 9, 2002 (JP) 2002-200022

(51) Int. Cl. H01L 29/04; H01L 31/036; H01L 31/0376; H01L 31/20

(52) U.S. Cl. 257/53

(57) ABSTRACT

In a region where a light-receiving face of a photodiode is located, when a first interconnection and a second interconnection are patterned, respective layers are removed. After a second interlayer insulating film and a cover insulating film are formed respectively as well, respective layers are removed. On the other hand, a protection insulating film is not removed by etching in the region where the light-receiving face of the photodiode is located, and an antireflection coating is still covered with the protection insulating film. Thus, a semiconductor device attaining reduction in the number of process steps without lowering light reflectivity, as well as an optical device can be obtained.

### BACKGROUND OF THE INVENTION

1. Field of the Invention

The present invention relates to a semiconductor device and an optical device including the same, and more particularly to a semiconductor device having a photodiode, and an optical device including such a semiconductor device.

2. Description of the Background Art

A photodiode is capable of converting an optical signal to an electrical signal, and has widely been used, for example, in a control optical sensor in a variety of photoelectric converters. In order to improve the sensitivity of the photodiode, an antireflection coating for preventing reflection of incident light is formed on the photodiode.

A silicon oxide film and a silicon nitride film are employed as an antireflection coating. For example, a silicon oxide film of a film thickness of approximately 32 nm is formed on the photodiode, and a silicon nitride film of a film thickness of approximately 55 nm is further formed on the silicon oxide film. This will achieve light reflectivity of not larger than 6% with respect to light having a wavelength of 780 nm and 650 nm respectively.

The light of a wavelength of 780 nm is applied for reading or writing information in a CD (Compact Disk) or a MD (Mini Disk), for example. On the other hand, the light of a wavelength of 650 nm is applied for reading or writing information in a DVD (Digital Versatile Disk).

Reflectivity by an antireflection coating is dependent on its film thickness to a large extent. Therefore, in a process step after the antireflection coating is formed, it is necessary to avoid reduction in the film thickness of the antireflection coating due to etching.

To that end, for example, a silicon oxide film for protecting the antireflection coating is formed immediately after the antireflection coating is formed. After a subsequent, prescribed process step, eventually, a cover insulating film is formed. After the further, prescribed etching step, the silicon oxide film that has protected the antireflection coating is subjected to wet etching for removal. Thus, reduction in film thickness of the antireflection coating is prevented.

FIG. 5 shows one example of a semiconductor device including such a conventional photodiode. As shown in FIG. 5, a semiconductor substrate 101 is provided with a region T where an NPN transistor is formed and a region PD where a photodiode is formed.

An example of a manufacturing method of the semiconductor device will now be described. For example, on the surface of P⁻ type silicon substrate 101 of a resistivity of 60Ω·cm, an N⁺ type embedment region 102 serving as a collector region of the NPN transistor and a P⁺ type element isolation region 104 are selectively formed. Next, on P⁻ type silicon substrate 101, an N-type epitaxial layer 103 having a resistivity of 2Ω·cm and a film thickness of approximately 2 μm is formed.

Then, an element isolation insulating film 105 made of the silicon oxide film is formed on N-type epitaxial layer 103, for example, by LOCOS. Element isolation is achieved by element isolation insulating film 105, P⁺ type element isolation region 104, and P⁻ type silicon substrate 101. Here, P⁺ type element isolation region 104 is also used as an anode extraction portion (electrode) of the photodiode.

On the other hand, in region PD, a silicon oxide film 116a of a film thickness of approximately 32 nm is formed, for example, with a thermal oxidation method, and an N⁺ type region 111 is formed in N-type epitaxial layer 103. Then, a silicon nitride film 116b of a film thickness of approximately 55 nm is formed by CVD (Chemical Vapor Deposition).

Thereafter, the silicon nitride film located in the region other than a region S where the light-receiving face of the photodiode is located is removed by prescribed photolithography and etching. An antireflection coating 116 is thus formed on region PD.

Next, in region T where the NPN transistor is formed, an N⁺ type collector region 106 is formed in one region surrounded by element isolation insulating film 105. A P-type base region 110 is then formed in N-type epitaxial layer 103 in another region surrounded by element isolation insulating film 105.

Then, an insulating film 107 made of the silicon oxide film, for example, is formed. Next, an N⁺ type polysilicon layer 114 serving as a contact region of an emitter is formed in insulating film 107 located on P-type base region 110. Here, N⁺ type polysilicon layer 114 is also formed in a photodiode region as a cathode extraction portion (electrode).

Thereafter, a prescribed anneal treatment is performed to diffuse n-type impurities in N⁺ type polysilicon layer 114, whereby an N-type emitter region 108 is formed. In this manner, an NPN transistor having N-type emitter region 108, P-type base region 110, and N⁺ type collector region 106 is formed.

Thereafter, a first interlayer insulating film 112 made of the silicon oxide film, for example, is formed so as to entirely cover the NPN transistor and the photodiode. A contact hole is formed in a prescribed region of insulating film 105 and first interlayer insulating film 112, and then, for example, titanium, tungsten, aluminum or the like is deposited, thereby forming a first interconnection 115.

A second interlayer insulating film 113 made of the silicon oxide film and the silicon nitride film, for example, is then formed so as to cover first interconnection 115. A second interconnection 117 made of aluminum, for example, is formed on second interlayer insulating film 113. A cover insulating film 118 made of the silicon nitride film, for example, is formed on second interconnection 117.

When first interconnection 115 and second interconnection 117 described above are patterned, a portion of region S where the light-receiving face of the photodiode is located is removed. In addition, the portion of region S where the light-receiving face of the photodiode is located is also removed after second interlayer insulating film 113 and cover insulating film 118 are formed respectively.

Thus, at a stage in which cover insulating film 118 is formed, the surface of first interlayer insulating film 120 is exposed in region S where the light-receiving face of the photodiode is located, while antireflection coating 116 is protected by first interlayer insulating film 120. Thereafter, first interlayer insulating film 120 in region S where the light-receiving face is located is removed by wet etching, to expose antireflection coating 116.

Next, the silicon substrate (wafer) that has undergone the process for manufacturing the NPN transistor and the photodiode is subjected to dicing, to form semiconductor chips. The individual semiconductor chip is attached to a leadframe with silver paste or the like, and molded by means of a molding insulating film 119. A semiconductor device with a photodiode is completed in such a manner.

On the other hand, a conventional semiconductor device described above has problems in the following. In a semiconductor device with the photodiode, antireflection coating 116 is formed on the photodiode in order to improve the sensitivity of the photodiode. Here, reflectivity by antireflection coating 116 is dependent on its film thickness to a large extent.

Therefore, in a process step after antireflection coating 116 is formed, first interlayer insulating film 120 for protecting antireflection coating 116 is formed so that the film thickness of antireflection coating 116 is not reduced by etching.

First interlayer insulating film 120 is eventually removed by wet etching, as described above. Accordingly, additional process step has been necessary.

In addition, when a semiconductor chip is molded by means of the molding insulating film, antireflection coating 116 is exposed in region S where the light-receiving face of the photodiode is located. As such, difference in height between region S and other regions is relatively large, and it is likely that air remains in such a stepped portion. This may cause variation in light sensitivity.

### SUMMARY OF THE INVENTION

The present invention was made to solve the above-described problems. One object of the present invention is to provide a semiconductor device that achieves reduction in the number of process steps without deteriorating light reflectivity. Another object thereof is to provide an optical device including such a semiconductor device.

A semiconductor device according to one aspect of the present invention includes a light-receiving element, an antireflection coating, a protection film, and a mold material. The light-receiving element has a light-receiving face formed on a main surface of a semiconductor substrate. The antireflection coating is formed so as to cover the light-receiving face of the light-receiving element, and formed by a prescribed layer for preventing reflection of incident light. The protection film is formed on the antireflection coating, and protects the same. The mold material is formed on the semiconductor substrate so as to directly cover the protection film.

In the conventional semiconductor device, the mold material has been formed on the semiconductor substrate so as to directly cover the antireflection coating. On the other hand, in the present configuration, the protection film is located on the antireflection coating. Therefore, it is not necessary to remove the protection film in the region where the light-receiving face of the light-receiving element is located, and reduction in the number of process steps can be achieved. In addition, light reflectivity can be suppressed to a relatively low value, even if the film thickness of the protection film is varied.

In addition, preferably, difference in an index of refraction between the protection film and the mold material is not larger than 0.3.

Accordingly, reflectivity with respect to light of a wavelength of 780 nm and 650 nm respectively can be suppressed to not larger than 10%, regardless of variation in film thickness of the protection film.

Specifically, such a protection film preferably includes a silicon oxide film or a polyimide-based resin.

Preferably, the semiconductor device further includes a signal processing circuit portion for processing a prescribed signal, formed in a region of the semiconductor substrate different from a region where the light-receiving element is formed.

In this case, preferably, the semiconductor device further includes a first insulating film formed so as to cover the signal processing circuit portion, and the protection film includes a film formed with a layer identical to the first insulating film.

In addition, preferably, the semiconductor device further includes a first interconnection formed on the semiconductor substrate with a second insulating film interposed, and the protection film includes a film formed with a layer identical to the second insulating film.

Moreover, preferably, the semiconductor device further includes a third insulating film formed so as to cover the first interconnection, and the protection film includes a film formed with a layer identical to the third insulating film.

Furthermore, preferably, the semiconductor device further includes a second interconnection formed on the third insulating film, and a fourth insulating film formed so as to cover the second interconnection, and the protection film includes a film formed with a layer identical to the fourth insulating film.

Thus, the protection film can be formed simultaneously with the step of forming the signal processing circuit portion.

An optical device according to another aspect of the present invention is an optical device including the semiconductor device according to claim 1.

According to this optical device, reflectivity of light can be suppressed to a relatively low value, and in addition, manufacturing cost thereof can be reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross-sectional view of a semiconductor device in a first embodiment of the present invention.

FIG. 2 illustrates dependency of light reflectivity on a film thickness of a protection insulating film in the first embodiment.

FIG. 3 is a cross-sectional view of a semiconductor device in a second embodiment of the present invention.

FIG. 4 illustrates dependency of light reflectivity on an index of refraction of a molding insulating film in the second embodiment.

FIG. 5 is a cross-sectional view of a conventional semiconductor device.

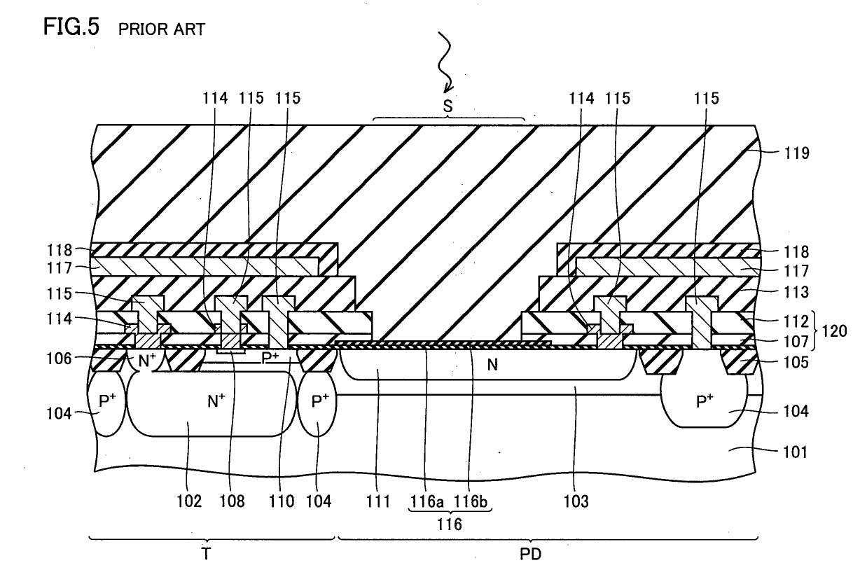

### DESCRIPTION OF THE PREFERRED EMBODIMENTS

First Embodiment

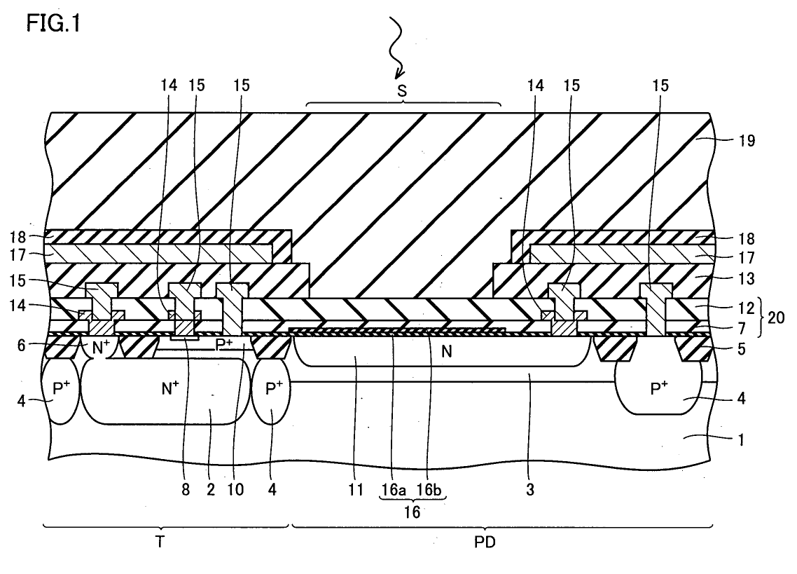

A semiconductor device in the first embodiment of the present invention will be described. A semiconductor device shown in FIG. 1 represents a light-receiving element containing a circuit having a photodiode and a bipolar element mounted. As shown in FIG. 1, an NPN transistor is formed in region T on the left side when facing the sheet surface, while the photodiode is formed in region PD on the right.

A process step for forming the NPN transistor and the photodiode is similar to that in the conventional method. For example, on the surface of a P⁻ type silicon substrate 1 of a resistivity of 60Ω·cm, an N⁺ type embedment region 2 serving as a collector region of the NPN transistor and a P⁺ type element isolation region 4 are selectively formed.

Next, on the surface of P⁻ type silicon substrate 1, an N-type epitaxial layer 3 having a resistivity of 2 μcm and a film thickness of approximately 2 μm is formed. Then, an element isolation insulating film 5 made of the silicon oxide film is formed on N-type epitaxial layer 3, for example, by LOCOS.

Here, element isolation is achieved by element isolation insulating film 5, P⁺ type element isolation region 4, and P⁻ type silicon substrate 1. P⁺ type element isolation region 4 is also used as an anode extraction portion (electrode) of the photodiode.

On the other hand, in region PD where the photodiode is formed, a silicon oxide film 16a of a film thickness of approximately 32 nm is formed, for example, with a thermal oxidation method, and an N⁺ type region 11 is formed in N-type epitaxial layer 3. Then, a silicon nitride film 16b of a film thickness of approximately 55 nm is formed by CVD.

Thereafter, the silicon nitride film located in the region other than region S where the light-receiving face of the photodiode is located is removed by prescribed photolithography and etching. An antireflection coating 16 is thus formed.

Next, in an NPN transistor region, an N⁺ type collector region 6 is formed in one region surrounded by element isolation insulating film 5. A P-type base region 10 is then formed in N-type epitaxial layer 3 in another region surrounded by element isolation insulating film 5.

Then, an insulating film 7 made of the silicon oxide film, for example, is formed. Next, an N⁺ type polysilicon layer 14 serving as a contact region of an emitter is formed in insulating film 7 located on P-type base region 10. Here, N⁺ type polysilicon layer 14 is also formed in a region PD where the photodiode is formed, as a cathode extraction portion (electrode).

Thereafter, a prescribed anneal treatment is performed to diffuse n-type impurities in N⁺ type polysilicon layer 14, whereby an N-type emitter region 8 is formed. In this manner, an NPN transistor having N-type emitter region 8, P-type base region 10, and N⁺ type collector region 6 is formed.

Next, a first interlayer insulating film 12 made of the silicon oxide film, for example, is formed so as to entirely cover the NPN transistor and the photodiode. A contact hole is formed in a prescribed region of insulating film 5 and first interlayer insulating film 12, and then, for example, titanium, tungsten, aluminum or the like is deposited, whereby a first interconnection 15 is formed.

A second interlayer insulating film 13 made of a layered film constituted with the silicon oxide film and the silicon nitride film, for example, is then formed so as to cover first interconnection 15. A second interconnection 17 made of aluminum, for example, is formed on second interlayer insulating film 13. A cover insulating film 18 made of the silicon nitride film, for example, is formed on second interconnection 17.

When first interconnection 15 and second interconnection 17 described above are patterned, a portion of region S where the light-receiving face of the photodiode is located is removed. In addition, the portion of region S where the light-receiving face of the photodiode is located is also removed after second interlayer insulating film 13 and cover insulating film 18 are formed respectively.

At a stage in which cover insulating film 18 is formed, only a protection insulating film 20 made of insulating film 7 and first interlayer insulating film 12 is left on antireflection coating 16 in region S where the light-receiving face of the photodiode is located. Protection insulating film 20 is not removed later by etching as in the conventional semiconductor device, and antireflection coating 16 is still covered with protection insulating film 20.

Thereafter, the silicon substrate (wafer) that has undergone the process for manufacturing the NPN transistor and the photodiode is subjected to dicing, to form semiconductor chips. The individual semiconductor chip is attached to a leadframe with silver paste or the like, and molded by means of a molding insulating film 19 such as a transparent molding resin. In such a manner, a semiconductor device with a photodiode is completed.

The semiconductor device according to the present invention formed in the above-described manner is different from the conventional semiconductor device in that protection insulating film 20 made of insulating film 7 and first interlayer insulating film 12 is left on antireflection coating 16.

Here, dependency on film thickness of protection insulating film 20, of reflectivity of a layered film constituted with antireflection coating 16 (silicon oxide film 16a and silicon nitride film 16b), protection insulating film 20 (insulating film 7 and first interlayer insulating film 12), and molding insulating film 19 has been evaluated.

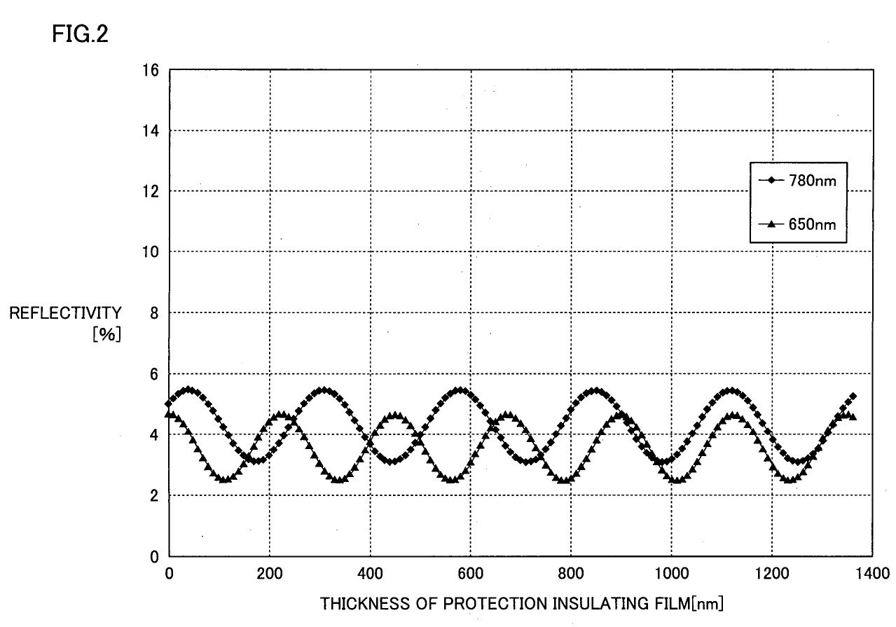

The result is shown in FIG. 2. FIG. 2 shows reflectivity with respect to light of a wavelength of 780 nm and 650 nm respectively. Here, it is assumed that the indices of refraction of silicon oxide film 16a, silicon nitride film 16b, and molding insulating film 19 have been set to 1.45, 2.00, and 1.54, respectively.

As described already, the light of a wavelength of 780 nm is applied for reading or writing information in a CD or a MD, for example, while the light of a wavelength of 650 nm is applied for reading or writing information in a DVD.

As shown in FIG. 2, even if the film thickness of protection insulating film 20 may vary, reflectivity can always attain a value not larger than 6%. In addition, the range of variation in reflectivity attains to approximately 3%, and an excellent reflectivity property can be obtained.

According to the semiconductor device described above, a desired low reflectivity can be obtained without a process step to remove protection insulating film 20 in region S where the light-receiving face of the photodiode is located, thereby attaining reduction in the number of process steps.

In addition, as protection insulating film 20 is not removed, a difference in height between region S where the light-receiving face of the photodiode is located and other regions can be made smaller. Therefore, when a semiconductor chip is molded by means of the molding insulating film, it is possible to prevent the air from remaining in a portion of the region where the photodiode is formed.

Further, insulating film 7 and first interlayer insulating film 12 constituting protection insulating film 20 can be formed simultaneously with the step of forming a transistor on semiconductor substrate 1.

Second Embodiment

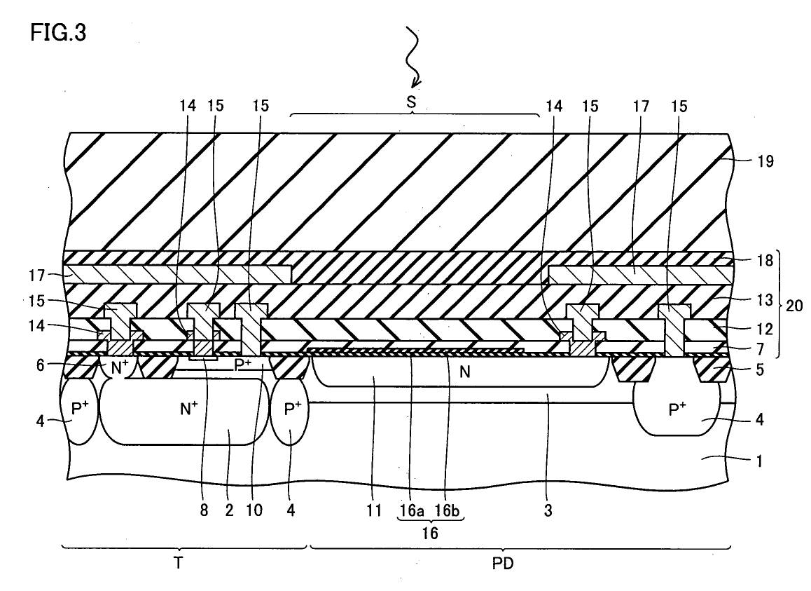

A semiconductor device in the second embodiment of the present invention will be described. In the semiconductor device shown in FIG. 3, a single-layered silicon oxide film is employed as second interlayer insulating film 13, and a polyimide-based resin is employed as cover insulating film 18. In addition, second interlayer insulating film 13 and cover insulating film 18 are not removed but remain on first interlayer insulating film 12 in region S where the light-receiving face of the photodiode is located.

Configuration is otherwise the same as the semiconductor device shown in FIG. 1 described in conjunction with the first embodiment. Therefore, same reference characters are given to same components, and description thereof will not be repeated.

According to the present semiconductor device, as in the semiconductor device described previously, first, a desired low reflectivity can be obtained without a process step to remove protection insulating film 20 in region S where the light-receiving face of the photodiode is located, thereby attaining reduction in the number of process steps.

In addition, since insulating film 7, first interlayer insulating film 12, second interlayer insulating film 13, and cover insulating film 18 serve as protection insulating film 20, a difference in height in region S where the light-receiving face of the photodiode is located can further be made smaller. Moreover, resistance to moisture can be improved by employing the polyimide-based resin as cover insulating film 18.

Even when protection insulating film 20 has a film thickness larger than that in the example. of the semiconductor device described previously, a low reflectivity is achieved with respect to a relatively wide range of thickness of protection insulating film 20, whereby light reflectivity can be maintained to a relatively low value.

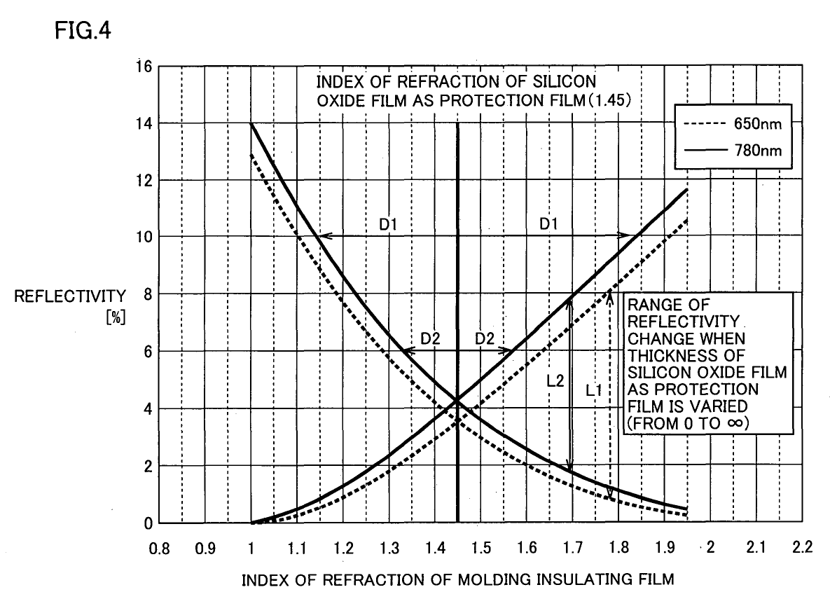

FIG. 4 shows dependency of reflectivity when the semiconductor device is molded by means of molding insulating film 19 on the index of refraction of molding insulating film 19. Reflectivity range represents a range of reflectivity variation when the film thickness of the silicon oxide film serving as protection insulating film 20 is varied; a range L1 represents a range of reflectivity with respect to the light of a wavelength of 650 nm; and a range L2 represents a range of reflectivity with respect to the light of a wavelength of 780 nm.

As shown in FIG. 4, in order to suppress the reflectivity with respect to light of a wavelength of 780 nm and 650 nm respectively to not larger than 10% regardless of variation in film thickness of protection insulating film 20, preferably, a difference D1 between the index of refraction (1.45) of the silicon oxide film serving as protection insulating film 20 and the index of refraction of molding insulating film 19 is not larger than 0.3.

As described above, if difference D1 in the index of refraction between protection insulating film 20 and molding insulating film 19 is not larger than 0.3, change in reflectivity due to variation in film thickness of protection insulating film 20 can be made relatively small. Accordingly, antireflection coating 16 located under such protection insulating film 20 is protected by protection insulating film 20.

In addition, in order to suppress the reflectivity to not larger than 6% so as to attain sufficient sensitivity of the photodiode, preferably, a difference D2 in the index of refraction between the silicon oxide film serving as protection insulating film 20 and molding insulating film 19 is not larger than 0.1. Thus, light sensitivity of the photodiode can be improved.

Though an NPN transistor has been employed as an example of a transistor formed on the semiconductor substrate in each embodiment described above, a PNP transistor, an MOS transistor, or the like may be formed. In addition, an element such as a resistance and a capacitance may be formed other than the transistor.

Moreover, though a photodiode has been described as an example of a light-receiving element, the light-receiving element is not limited thereto, so long as the element receives light of a prescribed wavelength and converts it to a signal.

With regard to an antireflection coating, an antireflection coating allowing modification of configuration and film thickness thereof in accordance with a wavelength of a signal light, and made of a single silicon nitride film layer, or made of a film formed by two or more layers, for example, is applicable.

The semiconductor device itself as described above can serve as a single light-receiving device, or alternatively, the semiconductor device can be applied to an optical device such as a hologram laser unit integrated with a semiconductor laser element, hologram and a condensing lens, and the like.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device, comprising:
a light-receiving element having a light-receiving face formed on a main surface of a semiconductor substrate;
an antireflection coating formed so as to cover the light-receiving face of said light-receiving element, and formed by a prescribed layer for preventing reflection of incident light;
a protection film formed on said antireflection coating and protecting said antireflection coating; and
a mold material formed on said semiconductor substrate so as to directly cover said protection film.

2. The semiconductor device according to claim 1, wherein said protection film has an index of refraction different from that of said mold material by at most 0.3.

3. The semiconductor device according to claim 1, wherein said protection film includes a silicon oxide film.

4. The semiconductor device according to claim 1, wherein said protection film includes a polyimide-based resin.

5. The semiconductor device according to claim 1, further comprising a signal processing circuit portion for processing a prescribed signal, formed in a region of said semiconductor substrate different from a region where said light-receiving element is formed.

6. The semiconductor device according to claim 5, further comprising a first insulating film formed so as to cover said signal processing circuit portion, wherein
said protection film includes a film formed with a layer identical to said first insulating film.

7. The semiconductor device according to claim 6, further comprising a first interconnection formed on said semiconductor substrate with a second insulating film interposed, wherein
said protection film includes a film formed with a layer identical to said second insulating film.

8. The semiconductor device according to claim 7, further comprising a third insulating film formed so as to cover said first interconnection, wherein
said protection film includes a film formed with a layer identical to said third insulating film.

9. The semiconductor device according to claim 8, further comprising a second interconnection formed on said third insulating film, and a fourth insulating film formed so as to cover said second interconnection, wherein
said protection film includes a film formed with a layer identical to said fourth insulating film.

10. An optical device comprising a semiconductor device according to claim 1.
